(19) United States
(12) Patent Application Publication
(10) Pub. No.: US 2007/0123007 A1
(43) Pub. Date: May 31, 2007

(54) Film-forming method and film-forming equipment

(75) Inventors: Hiroshi Furutani, Numazu-shi (JP); Michio Nishibayashi, Numazu-shi (JP); Seiichi Nakazawa, Numazu-shi (JP); Shinichi Mitani, Numazu-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: NuFlare Technology, Inc.

(21) Appl. No.: 11/604,841

(22) Filed: Nov. 28, 2006

(30) Foreign Application Priority Data
Nov. 30, 2005 (JP) P2005-346580

(51) Int. Cl. C23C 16/00; H01L 21/20

(52) U.S. Cl. 438/478; 118/715; 427/248.1; 118/719

(57) ABSTRACT

A plurality of wafers are loaded on a susceptor installed in a reaction chamber, and the wafers are heated, and process gas is fed from a plurality of stages of openings formed in a gas feed nozzle installed so as to pass through the center of the susceptor, the process gas is fed obliquely downward from the uppermost openings, and the process gas feeding directions are changed to the reaction chamber relatively. The thickness of deposits on the wall of the reaction chamber is suppressed, the maintenance cycle of film forming equipment is extended, and the throughput can be improved.

### CROSS-REFERENCE TO RELATED APPLICATIONS

This application is based upon and claims the benefit of priority from the prior Japanese Patent Application No. 2005-346580 filed on Nov. 30, 2005, the entire contents of which are incorporated herein by reference.

### BACKGROUND OF THE INVENTION

1. Field of the Invention

The present invention relates to a film forming method and film forming equipment, for example, used for epitaxial gas-phase growth.

2. Description of the Related Art

At the manufacturing step of a semiconductor apparatus, for example, using film forming equipment such as a vertical epitaxial gas-phase growth device, an epitaxial film is formed on a wafer.

Generally, in the vertical epitaxial gas-phase growth device, for example, as described in Japanese Patent Application KOKAI Publication No. 10-312966, in a reaction chamber comprised of a quartz bell jar, a susceptor for loading a plurality of wafers, and at the upper part of a gas feed pipe passing through the central part of the susceptor, a gas feed nozzle with plurality of openings for feeding process gas onto wafers is arranged. Below the susceptor, a heating means for heating the wafers and a rotating means for rotating the susceptor are installed. To the lower part of the film forming chamber, an exhausting means for exhausting gas is connected.

Using such a vertical epitaxial gas-phase growth device, epitaxial films are formed on wafers. The susceptor loading a plurality of wafers is rotated, thus process gas is fed onto the wafer surfaces from the gas feed nozzles. At this time, process gas fed from the gas feed nozzles passes on the susceptor and flows to the exhausting means. In this case, a part of process gas collides with the quartz bell jar at a comparatively low temperature and deposits. When the amount of deposits increases, a part thereof drift up as particles and the particles onto the wafers on an air current in the reaction chamber. Therefore, at the point of time when a fixed amount of the deposit, it is necessary to perform maintenance of the inside of the reaction chamber.

Generally, from the gas feed nozzle, process gas is fed in fixed directions (for example, three directions at every 120°). Therefore, it deposits at the same area of the quartz bell jar, thus amount of the deposit thereof is varied. Actually, maintenance cycle depends on the maximum value of the deposit. Therefore, by suppressing variations in amount of the deposit, it can be expected to extend the maintenance cycle and improve the throughput.

A method for suppressing variations in the deposited amount on the wafer surfaces is proposed in Japanese Patent Application KOKAI Publications No. 2000-58463 and No. 8-88187. However, they are not for referring to variations in the deposited amount on the inner wall of the reaction chamber.

### SUMMARY OR THE INVENTION

An object of the present invention is to provide a film forming method and film forming equipment for extending the maintenance cycle of the film forming equipment and improving the throughput thereof.

In the film forming method of an embodiment of the present invention begins loading a plurality of wafers on a susceptor installed in a reaction chamber, heating the wafers, feeding process gas from a plurality of stages of openings formed in a gas feed nozzle installed so as to pass through a center of the susceptor, feeding the process gas obliquely downward from an uppermost openings among the plurality of stages of openings formed, and changing process gas feeding directions from the plurality of stages of the openings to the reaction chamber relatively.

The film forming equipment of an embodiment of the present invention includes a reaction chamber for forming a film on a wafer, a susceptor for loading a plurality of the wafers, a heater installed right under or inside the susceptor for heating the wafers, a gas feed nozzle installed so as to pass through a central part of the susceptor, having a plurality of stages of openings for feeding process gas onto the wafers, a rotating mechanism for changing the openings relatively to the reaction chamber, and the uppermost stage of the openings have projections for feeding the process gas obliquely downward.

Additional objects and advantage of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a cross sectional view of the vertical epitaxial gas-phase growth device relating to an embodiment of the present invention.

FIG. 2 is a side view of the gas feed nozzle 5.

FIG. 3 is a top view of the gas feed nozzle 5.

FIG. 4 is a drawing showing the film thickness distribution of the epitaxial film formed by using the film forming equipment shown in FIG. 1.

FIG. 5 is a conceptual diagram of the top of flow of process gas at time of film forming relating to an embodiment of the present invention.

FIG. 6 is a conceptual diagram of the section of flow of process gas at time of film forming relating to an embodiment of the present invention.

FIG. 7 is a cross sectional view of the vertical epitaxial gas-phase growth device relating to an embodiment of the present invention.

FIG. 8 is across-sectional view of the vertical epitaxial gas-phase growth device relating to an embodiment of the present invention.

### DETAILED DESCRIPTION OF THE EMBODIMENTS

Hereinafter, the embodiments relating to the present invention will be explained with reference to the accompanying drawings.

FIG. 1 shows a cross sectional view of the vertical epitaxial gas-phase growth device of this embodiment. As shown in the drawing, in a film forming chamber 2 which is a reaction chamber for forming a film on a wafer 1 comprised of a quartz bell jar, a susceptor 3 for loading a plurality of wafers 1 is installed.

A gas feed pipe 4 for feeding film forming gas from underneath the film forming chamber 2 is arranged. To the upper part of the gas feed pipe 4, a gas feed nozzle 5 is connected. The gas feed nozzle 5 passes through the central part of the susceptor 3 and thereon, openings for feeding film forming gas onto the wafers 1 from above the susceptor 3 are formed.

Below the susceptor 3, a heating means 6 such as an RF coil for heating the wafers 1 via the susceptor 3 and a rotating means 7 for rotating the susceptor 3 are installed. An exhausting means 8 for exhausting gas is connected to the lower part of the film forming chamber 2. Furthermore, a nozzle rotation control mechanism 9 connected to the gas feed pipe 4 for rotating the gas feed nozzle 5 at a predetermined angle is installed.

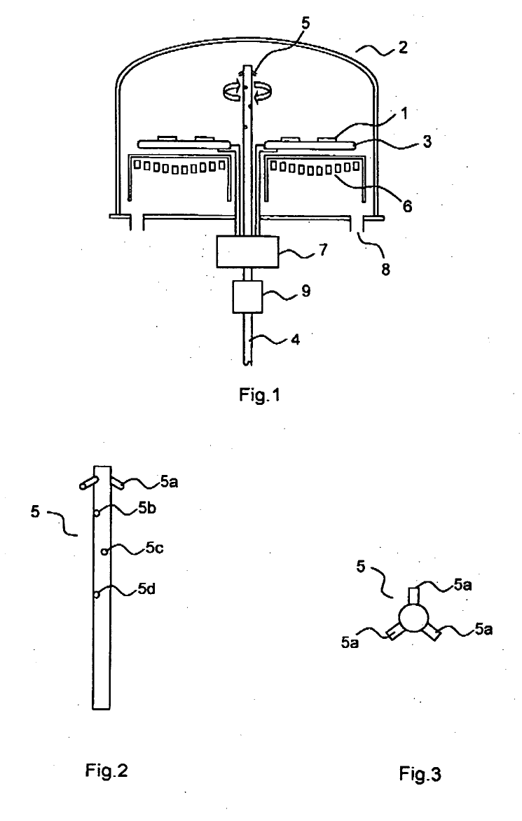

FIG. 2 shows a side view of the gas feed nozzle 5 and FIG. 3 shows a top view of the gas feed nozzle 5. As shown in the drawings, openings 5a, 5b, 5c, and 5d which are formed in three directions, for example, every 120° at predetermined intervals and phases, and for example, at four stages are installed. Only the uppermost openings 5a have projections (branches) for feeding process gas obliquely downward. Here, it is necessary that the gas feeding directions (the directions of the projections (branches)) are not horizontal, that is, an angle γ of the projections with the central axis of the gas feed nozzle 5 is smaller than 90°. When an angle formed between the line connecting the edge of the susceptor and the center of the uppermost openings (the base of the projections (branches) and the central axis of the gas feed nozzle 5 as β, the following relation is preferable:
|≦γ≦0.3β+63 (degrees)
When γ is smaller than β, it is difficult to feed gas evenly onto all the wafers 1. On the other hand, when γ is larger than (0.3β+63), gas flows toward the wall of the film forming chamber 2, thus it is difficult to feed gas efficiently onto the wafers 1.

And, at the second stage at the same phase under the uppermost stage (first stage) and the third stage at a different phase of the first stage and the second stage, the openings 5b and 5c for respectively feeding gas to the horizontal direction are sequentially installed. And, at the lowermost stage (fourth stage), the openings 5d at the same phase as that of the uppermost stage (first stage) for feeding gas to the horizontal direction as same as the second stage and third stage is installed. The gas feed nozzle 5 can rotate to change the feeding direction of process gas by proper rotation.

Epitaxial films are formed on the wafers 1, by using such a vertical epitaxial gas-phase growth device. Firstly, wafers 1 such as ten 4-inch wafers are loaded on the susceptor 3. The process gas including raw material gas such as monosilane and trichlorosilane at a mixture ratio of, for example, 140 SLM of H₂ gas and 10.5 SLM of trichlorosilane is fed onto the wafers 1 from a gas feed means (not drawn) via the gas feed pipe 4, from the gas feed nozzle 5. The wafers 1 are heated, for example, to 1130° C. by the heating means 6 and the process gas is reduced by hydrogen or is decomposed by heating and is deposited by rotating the susceptor 3. In this way, epitaxial films are formed on the wafers 1.

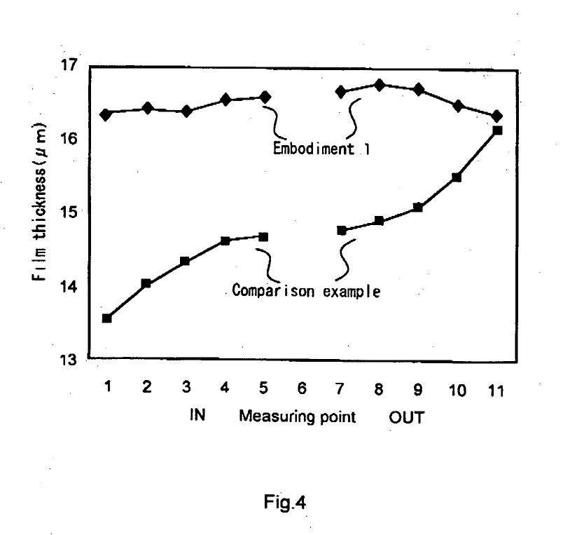

The film thickness distribution of the epitaxial film formed in this way is shown in FIG. 4. As shown in the drawing, there are no large variations in the film thickness and a good film thickness distribution is obtained. Further, a comparison example in which the process gas is fed horizontally from the uppermost openings are also shown. As shown in the drawing, the process gas is fed obliquely downward from the uppermost openings 5a, thus variations in the film thickness of the epitaxial film formed are reduced and the film thickness is increased.

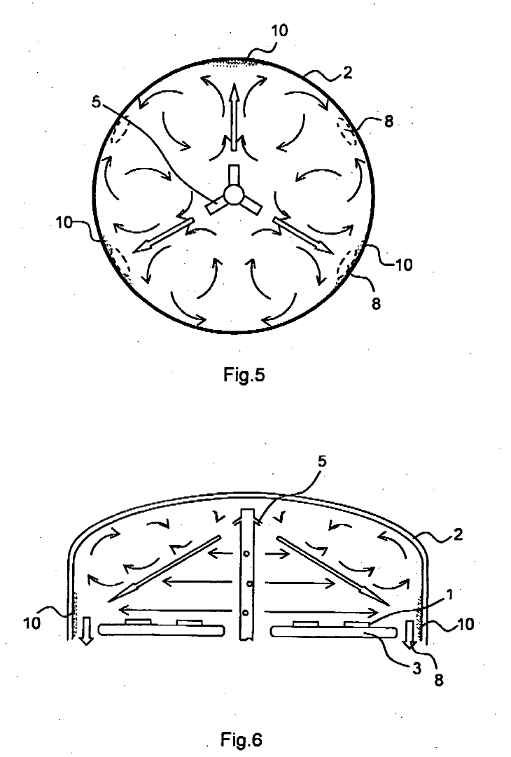

FIG. 5 shows a horizontal conceptual diagram of flow of process gas at time of film forming and FIG. 6 shows a conceptual diagram of the section thereof in the vertical direction. As shown in the drawings, the process gas fed from the gas feed nozzle 5 is fed obliquely downward from the uppermost openings 5a, so that the flow of gas to the upper part of the film forming chamber 2 is suppressed and the process gas is fed uniformly and efficiently onto the susceptor 3. Therefore, as mentioned above, the film thickness on the wafers 1 is increased and in the gas flow direction (three directions in this embodiment), deposits 10 formed by the gas being cooled at the wall of the film forming chamber 2 are increased, thus it may be considered that the influence thereof cannot be ignored.

In this way, epitaxial films with a predetermined film thickness are formed on the wafers 1, and then the film forming chamber 2 is exposed to the air, and the wafers are unloaded. At this time, the gas feed nozzle 5 is rotated 30° clockwise, for example, by the nozzle rotation control mechanism 9.

New wafers are loaded on the susceptor 3 in the same way, and the film forming process is performed, and then similarly, the gas feed nozzle 5 is rotated clockwise 30° again after the film forming process.

As mentioned above, it is possible to change the location of the deposits at the quartz bell jar in the horizontal direction, make the thickness of the deposits uniform, and suppress to increase the thickness of the deposits, whenever performing the film forming process, the gas feed nozzle is rotated, and the relative feeding direction of process gas to the film forming chamber is changed to the horizontal peripheral direction of the film forming chamber.

While every film forming process, the gas feed nozzle is rotated 30° clockwise in this embodiment, the rotational direction and rotational angle are not limited particularly. The rotational direction may be any direction when it is fixed and the rotational angle may be any angle when it is different from the phase difference (120° in this embodiment) of the respective openings of the gas feed nozzle 5.

### Embodiment 2

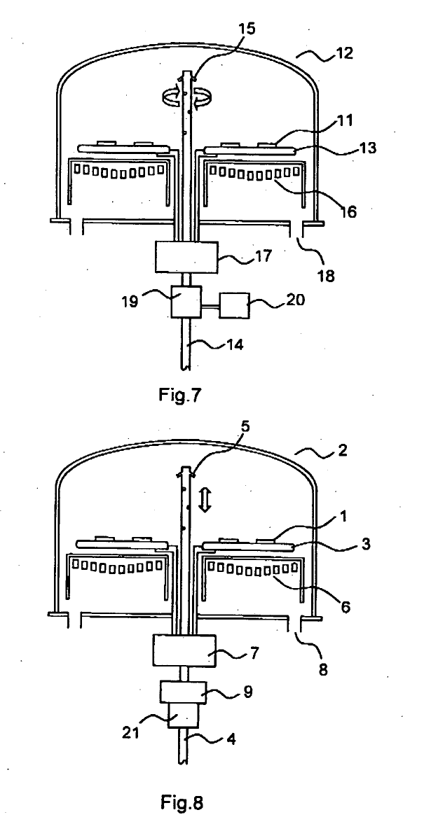

FIG. 7 shows a cross sectional view of the vertical epitaxial gas-phase growth device of this embodiment. It has a structure almost similar to that of Embodiment 1, though it is a difference that a nozzle rotation control mechanism 19 is equipped with a rotational speed control mechanism 20.

Epitaxial films are formed on wafers 11 by use of such a vertical epitaxial gas-phase growth device. Firstly, similarly to Embodiment 1, on a susceptor 13, the wafers 11 are loaded and process gas is fed onto the wafers 11 from a gas feed nozzle 15. The wafers 11 are heated by a heating means 16 and epitaxial films are formed on the wafers 11 by rotating the susceptor 13 at 6 to 10 rpm. At the same time, the gas feed nozzle 15 is rotated at a rotational speed of, for example, 0.1 rpm controlled by the nozzle rotation control mechanism 20.

As mentioned above, thus it is possible to change the location of the deposits in the quartz bell jar in the horizontal direction, make the thickness of the deposits uniform, and suppress to increase the thickness of the deposits.

While the gas feed nozzle 15 is controlled to rotated at 0.1 rpm in this embodiment, the rotational speed of the gas feed nozzle-15 is acceptable when it is lower than the rotational speed of the susceptor 13. For example, it may be set so as to rotate the gas feed nozzle 15 once for one film forming process.

Further, while the gas feed nozzles 5 and 15 are rotated in the embodiments, it is not limited to be rotated only when the relative feeding direction of the process gas to the film forming chamber can change. For example, as shown in FIG. 8, it is possible to connect the gas feed nozzle 5 of the film forming equipment shown in FIG. 1 to a nozzle vertical movement controller 21 so as to freely move up and down, drive it in the vertical direction, and additionally move it in the vertical peripheral direction of the film forming chamber. In this case, when a vertical sliding mechanism is installed on the nozzle rotation controller 9, the gas feed nozzle 5 can be driven so as to rotate and moreover to move vertically.

Further, while the susceptors 3 and 13 are rotated during film forming process in the embodiments, it is possible when the temperature distribution in the wafer surface can be made uniform, for example, the heating means 6 and 16 may be rotated.

Further, while ten 4-inch wafers are loaded on the susceptors 3 and 13 in the embodiments, the size and number of wafers are not restricted particularly and an appropriate number of 6-inch or 8-inch wafers can be loaded.

Further, while the lowermost (fourth) and uppermost (first) openings of the gas feed nozzles 5 and 15 have the same phase, the uppermost (first) and lowermost (fourth) openings 5a and 5b preferably have the same phase, to suppress diffusion of feed gas from the lowermost (fourth) openings most contributing to film forming by feed gas from obliquely above from the uppermost (first) openings. In this case, more deposits are formed at the same area, so that it is more effective to change the relative feeding direction of the process gas to the film forming chamber. Further, the intervals between the stages do not need to be the same. As shown in FIG. 2, the intervals between the first and second stages, between the second and third stages, and the interval between the third and the fourth stages may be different and all the intervals may be different.

According to these embodiments, the thickness of the deposits in the film forming chamber can be prevented to increase, so that the maintenance cycle can be extended. In wafers and semiconductor devices formed from the wafers via the device forming step and device separation step, without lowering the yield rate and the stability of the device characteristics, the throughput can be improved. Particularly, by application of the invention to a thick film forming process of a power semiconductor device such as a power MOSFET and an IGBT (an insulating gate type bipolar transistor) in which a thick film with a thickness of several tens of μm to 100 μm is used in the N-type base area, P-type base area, and insulating separation area, the process cost can be reduced greatly.

While the epitaxial film is formed on an Si substrate in this embodiment, it can be applied to forming of a polysilicon layer and it can be applied also to other compound semiconductors, for example, a GaAs layer, a GaAlAs layer, and an InGaAs layer. It can also be applied to forming of an SiO₂ film and an Si₃N₄ film, and in the case of SiO₂ film, monosilane (SiH₄) and gases of N₂, O₂, and Ar are fed, and in the case of Si₃N₄ film, monosilane (SiH₄) and gases of NH₃, N₂, O₂, and Ar are fed.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A film forming method comprising:
loading a plurality of wafers on a susceptor installed in a reaction chamber,
heating the wafers,
feeding process gas from a plurality of stages of openings formed in a gas feed nozzle installed so as to pass through a center of the susceptor,
feeding the process gas obliquely downward from an uppermost openings among the plurality of stages of openings formed, and
changing process gas feeding directions from the plurality of stages of the openings to the reaction chamber relatively.

2. The film forming method according to claim 1, wherein from each of the plurality of stages of the openings, the process gas is fed in three or more directions with a substantially equal phase difference.

3. The film forming method according to claim 1, wherein among the plurality of stages of the openings, at least the uppermost openings and lowermost openings have a same phase.

4. The film forming method according to claim 2, wherein the gas feed nozzle is rotated to change the process gas feeding directions from the openings to the reaction chamber relatively.

5. The film forming method according to claim 4, wherein the gas feed nozzle is rotated at a predetermined angle while the reaction chamber is opened to the air.

6. The film forming method according to claim 5, wherein the predetermined angle is different from the phase difference of the directions of feeding the process gas.

7. The film forming method according to claim 2, wherein the gas feed nozzle is rotated during the process gas being fed.

8. The film forming method according to claim 1, wherein from the uppermost openings, the process gas is fed in a direction at an angle of smaller than 90° with a rotary shaft of the gas feed nozzle.

9. The film forming method according to claim 1, wherein, the process gas is fed in a direction satisfying the following formula when an angle of the directions of feeding the process gas from the uppermost openings with a central axis of the gas feed nozzle as γ and an angle of a line connecting an edge of the susceptor and a center of a base of projections of the uppermost openings with the central axis of the gas feed nozzle as β:
β≦γ≦0.3β+63 (degrees)

10. The film forming method according to claim 1, wherein the gas feed nozzle moves up and down.

11. Film forming equipment comprising:
a reaction chamber for forming a film on a wafer,
a susceptor for loading a plurality of the wafers,
a heater installed right under or inside the susceptor for heating the wafers,
a gas feed nozzle, installed so as to pass through a central part of the susceptor, having a plurality of stages of openings for feeding process gas onto the wafers, and
a rotating mechanism for changing the openings relatively to the reaction chamber, wherein:
uppermost stage of the openings have projections for feeding the process gas obliquely downward.

12. The film forming equipment according to claim 11, wherein each stage of the openings are installed at three or more locations at a substantially equal angle in the peripheral direction.

13. The film forming equipment according to claim 11, wherein the uppermost stage of the openings and lowermost stage of the openings have a same phase.

14. The film forming equipment according to claim 11, wherein in the plurality of stages of openings, an interval of at least one stage is different from intervals of the other stages.

15. The film forming equipment according to claim 11, wherein the projections are configured for an angle between a direction for feeding the process gas and a central axis of the gas feed nozzle is smaller than 90°.

16. The film forming equipment according to claim 11, wherein the projections are installed so that the following formula is held when an angle between the directions for feeding the process gas and the central axis of the gas feed nozzle as γ and an angle between a line connecting an edge of the susceptor and a center of a base of the projections with the central axis of the gas feed nozzle as β:
β≦γ≦0.3β+63 (degrees)

17. The film forming equipment according to claim 11, wherein the rotating mechanism has a rotation control mechanism for controlling a rotational angle.

18. The film forming equipment according to claim 11, wherein the rotating mechanism has a rotational speed control mechanism for controlling a rotational speed.

19. The film forming equipment according to claim 11, further comprising a vertical movement control mechanism for moving the gas feed nozzle up and down.
